(19) United States
(12) Patent Application Publication
(10) Pub. No.: US 2022/0032336 A1
(43) Pub. Date: Feb. 3, 2022

(54) FLUID DEVICE

(71) Applicant: Festo SE & Co. KG, Esslingen (DE)

(72) Inventors: Martin Maichl, Salach (DE); Hannes Wirtl, Schongau (DE)

(21) Appl. No.: 17/387,363

(22) Filed: Jul. 28, 2021

(30) Foreign Application Priority Data
Jul. 30, 2020 (DE) 102020209593.0

(51) Int. Cl. B05C 11/10; H01L 41/09

(52) U.S. Cl. CPC B05C 11/1002; G05D 7/0629; H01L 41/0973

(57) ABSTRACT

A fluid device with a fluid chamber, the fluid device including a fluid chamber which is designed for receiving a fluid and which is commonly delimited by a device housing and a bending-elastic membrane element. The membrane element is fixed with a peripheral edge region to the device housing, wherein a membrane working section of the membrane element which is framed by the peripheral edge region can be deflected by a piezoactuator whilst carrying out a stroke movement, in order to change the volume of the fluid chamber. The membrane element is a functional constituent of the piezoactuator by way of it directly forming an electrically conductive electrode of the electrode arrangement of the piezoactuator.

### BACKGROUND OF THE INVENTION

The invention relates to a fluid device comprising a fluid chamber which is designed for receiving a fluid and which is commonly delimited by a device housing and a bending-elastic membrane element which has a planar extension in a main extension plane, wherein the membrane element at its peripheral edge region is fixed to the device housing and wherein a membrane working section of the membrane element which is framed by the peripheral edge region, for the change of the volume of the fluid chamber can be elastically deflected in a working direction which is orientated transversely to the main extension plane by a piezoactuator of the fluid device whilst carrying out a stroke movement, wherein the piezoactuator comprises an electrode arrangement, to which an operating voltage which creates the stroke movement of the membrane working section can be applied in a variable magnitude.

A fluid device of this type which known from JP-H03-12917 A is applied on manufacturing semiconductors and provides the possibility of sucking back a fluid which is located in a fluid channel, in order to avoid an undesired dripping at a delivery opening. The back-sucking effect can be created by way of an underpressure which can be generated in a fluid chamber of the fluid device, with which device the aforementioned fluid channel is in connection. The fluid chamber is commonly delimited by a device housing and by a membrane element which is fixed to the device housing at the edge side. The underpressure can be generated by way of a membrane working section of the membrane element which delimits the fluid chamber being deflected by way of a piezoactuator, so that the volume of the fluid chamber changes. The piezoactuator is designed as a stack translator and is fastened to the bending-elastic membrane element. The piezoactuator has several electrodes independently of the membrane element, to which electrodes an operating voltage can be applied, said operating voltage causing a deformation of the piezoactuator, wherein the membrane working section of the membrane element undergoes a corresponding deformation.

Concerning a suck back valve which is known from DE 198 10 657 A1, an underpressure which effects the sucking-back of a fluid can be generated by way of a deformable membrane, on which a piston engages, said piston being biased by a spring and whose movement is controllable by the controlled fluid impingement of a further membrane.

EP 0 504 465 A1 discloses an electrofluidic transducer for electrically controllable valves, said transducer being provided with a piezoelectric drive device which is designed as a disc translator.

### SUMMARY OF THE INVENTION

It is the object of the invention to provide measures which permit a simple and precise change of the volume of the fluid chamber of a fluid device.

For achieving the aforementioned object, in a fluid device comprising the aforementioned features the membrane element is a functional constituent of the piezoactuator by way of it directly forming an electrically conductive electrode of the electrode arrangement.

With regard to the fluid device according to the invention, the volume of a fluid chamber can be changed by way of a piezoactuator which with an electrode of its electrode arrangement itself directly forms a movable delimitation wall of the fluid chamber. The piezoactuator has an electrode arrangement, to which an operating voltage of a variable magnitude can be applied, from which a reversible shape change of the piezoelement results according to the inverse piezoeffect. The electrode which is used in a direct manner as a membrane element for delimiting the fluid chamber, in the region of its membrane working section participates in the shape change, which is manifested in a stroke movement transversely to the main extension plane of the electrode which represents the membrane element. Depending on the degree of the deflection which is caused by the operating voltage, the volume of the fluid chamber changes to a greater or lesser degree, wherein a volume increase can be used for example to generate an underpressure in the fluid chamber. Since no individual component which is independent of the function of the piezoactuator is used as a membrane element, but an electrode of the piezoactuator itself is used in a direct manner, the fluid device can be realised in a very inexpensive and compact manner Furthermore, the setting of the desired fluid chamber volume is possible in a more precise manner than given a combination of the piezoactuator with a membrane element which is separate with respect to this. The piezoactuator can be proportionally controlled in a very simple manner, in order to set different stroke positions for specifying different volumes. The operation is possible with a low energy level, so that despite a direct activation, no relevant intrinsic heating occurs. The piezoelectric concept further if necessary permits a closed-loop control of the position given the deflection of the membrane working section, so that accurately repeatable settings are possible.

Advantageous further developments of the invention are to be derived from the dependent claims.

The membrane element which forms an electrode of the piezoactuator expediently consists of an electrically conductive metal. The application of a stainless steel membrane is seen as being particularly expedient.

The membrane element has two membrane surfaces which are facing away from one another in the working direction. Apart from the electrode arrangement, the piezoactuator has at least one piezoelement which has piezoelectric characteristics and which is fixed on one of the two membrane surfaces of the membrane element. The piezoelement in particular consists of a piezeoceramic which has piezoelectric characteristics. A further electrode is located on the side of the piezoelement which is facing away from the membrane element in the working direction, so that this piezoelement is placed between two electrodes, to which the operating voltage which is necessary for the actuation of the piezoactuator can be applied.

The piezoelement can be fastened to the membrane element in an arbitrary manner, wherein however a large-surfaced bonding connection is particularly recommended.

The further electrode which lies opposite the electrode which functions as a membrane element expediently consist of an electrically conductive coating of the piezoelement, for example of a copper layer. Basically, the further electrode however can also be an individual electrode element as is the case with the electrode which forms the membrane element.

Basically, the piezoactuator can be attached to the one or the other of the two membrane surfaces of the membrane element which are orientated in the working direction. For avoiding a contact with a medium which is located in the fluid chamber, it is however advantageous if the piezoelement is attached to the membrane surface of the membrane element which is facing away from the fluid chamber.

The piezoelement preferably has a circular outer contour and in particular is arranged on one of the two membrane surfaces of the membrane element in the middle of the surface.

At its peripheral edge region, the membrane element expediently likewise has a circular outer contour. The piezoelement preferably has a smaller diameter than the membrane element.

Basically, the piezoactuator could be designed as a stack translator which comprises several piezoelements which are stacked onto one another and which are each placed between two electrodes of the electrode arrangement. However, a construction shape, concerning which the piezoactuator is a disc translator, is seen as being particularly advantageous and herein inexpensive and effective, wherein in particular it comprises only a single disc-like piezoelement which is arranged between two piezoelectrically inactive electrodes of the electrode arrangement, wherein one of these two electrodes forms the membrane element.

A construction shape as a disc translator is particularly effective since its actuation leads to a spherical sagging of the complete system, by way of which a volume change of the fluid chamber can be set in a particularly exact manner The application of an operating voltage to the electrodes which are assigned to the piezoelement causes an extension of the piezomaterial in the direction of the electrical field, thus here in the working direction, which leads to the disc-shaped piezoelement on the one hand becoming thicker and on the other hand simultaneously experiencing a reduction in its outer diameter. In combination with the piezoelectrically inactive electrode which functions as a carrier element for the piezoelement, this leads to the mentioned spherical deflection of the entire system consisting of the piezoelement and the electrode arrangement.

The membrane element is expediently designed in a gas-impermeable manner If it is furthermore connected at its edge region to the device housing in a fluid-tight manner all round, then a fluid-tight shielding of that region of the fluid device which is located on the side of the piezoactuator which is opposite to the fluid chamber can be achieved in a very reliable manner. A housing chamber for example can be provided there, said housing chamber receiving the further components of the piezoactuator which are seated on the membrane element, thus in particular the piezoelement and a further electrode. A separation of media is then present, which results in the advantage that the piezoactuator and possibly present electrical leads do not come into contact with fluid which is located or flows in the fluid chamber.

The membrane element at its edge region can for example be clamped or bonded in the device housing. If required, an additional sealing device can be present.

The fluid device preferably comprises an electronic control device which is electrically connected to the electrode arrangement on operation of the fluid device and by way of which the desired operating voltage is provided for the piezoactuator and which is designed in order to effect a charge feed and charge discharge with regard to the electrode arrangement in accordance with requirements. For example, the electronic control device comprises a high voltage stage. Depending on the magnitude of the applied operating voltage, a stroke movement of the membrane working section and a positioning of the membrane working section in a defined stroke position can be effected with the help of the control device, wherein the set stroke position each corresponds to a certain volume of the fluid chamber.

In order to be able to set the volume of the fluid chamber in a particularly precise and reproducible manner, it is advantageous if the fluid device is provided with a distance measuring device which is designed for measuring a distance between the piezoactuator and the device housing, said distance changing given the stroke movement of the membrane working section. Since the piezoactuator is expediently only suspended on the device housing via the membrane element which simultaneously functions as an electrode, given the stroke movement of the membrane working section the complete piezoactuator executes a corresponding stroke movement relative to the device housing, so that a distance measurement is possible at an arbitrary location.

It is particularly advantageous if the distance measuring device is designed such that the distance is measured where the deflection is largest given the stroke movement of the membrane working section. With regard to a disc translator, this is the centre region of the disc-like piezoelement.

Different measuring principles are considered for the distance measurement, for whose implementation the distance measuring device is designed. For example, a capacitive measurement between the electrode arrangement and the device housing is possible. Distance measurements are furthermore possible inductively with a planar coil, optically with a reflection light barrier, optically with a triangulator or magnetically with a Hall sensor. These however are only advantageous examples which are not to be understood as conclusive.

It is particularly favourable if the electronic control device is designed for a closed-loop controlled setting of the stroke position of the membrane working section, wherein the closed-loop control is effected on the basis of the distance measurement values which are determined by the distance measuring device. A closed-loop control of the volume of the fluid chamber is effected in an indirect manner by way of the closed-loop control of the distance, since the piezoactuator has a reproducible deformation behaviour and therefore an unambiguous assignment between the individual stroke positions of the membrane working section and the momentary volume of the fluid chamber exists.

The fluid device can be applied in arbitrary situations, in which it is a question of setting the volume of a fluid chamber in according with requirements. For example, a volume setting can be effected in order to specify a fluid volume which is of relevance to a subsequent metering procedure.

A particularly advantageous use for the fluid device lies in its application as a fluid suction device, wherein an underpressure can be created by a volume increase of the fluid chamber which is caused by way of the piezoactuator, by way of which underpressure fluid which is located in a first fluid channel which is connected to the fluid chamber can be sucked into the fluid chamber. By way of this, for example a post-dripping of liquid in the case of metering procedures can be prevented.

Metering procedures are commonplace in many fields, such as for example in medical technology or also with industrial applications and for example in circuit board manufacture on metering a photo resist onto circuit boards.

A particularly expedient fluid device has two fluid channels which communicate with the fluid chamber, wherein a first fluid channel is an exit channel, through which fluid which is located in the fluid chamber can flow out of the fluid chamber, whilst a second fluid channel is an entry channel, through which fluid can flow into the fluid chamber. A shut-off unit which is assigned to the second fluid channel can selectively release or block the second fluid channel, in order to permit or prevent a passage of fluid. Such a shut-off unit represents for example a metering valve if the fluid device is used as a metering device or as a constituent of a metering device. In order, after completion of a metering procedure, to prevent a post-dripping of liquid fluid, the piezoactuator is held in an operational state during the metering, with which operational state the fluid volume of the fluid chamber is reduced. After stopping the metering procedure, the fluid volume is enlarged by way of a suitable control of the piezoactuator, so that a desired quantity of fluid is sucked back out of the exit channel into the fluid chamber.

### BRIEF DESCRIPTION OF THE DRAWINGS

The invention is hereinafter explained in more detail by way of the accompanying drawings. There are shown in:

FIG. 1 in a schematic and partly sectioned representation, a preferred embodiment of the fluid device according to the invention in a first operating phase with a set, reduced fluid chamber volume,

FIG. 2 the fluid device in a second operating phase with a fluid chamber volume which is set larger in comparison to the first operating phase of FIG. 1 and

FIG. 3 a plan view upon a device unit of the fluid device which comprises the fluid chamber, with a viewing direction according to arrow III of FIG. 2.

### DETAILED DESCRIPTION

A fluid device which in its entirety is provided with the reference numeral 1 is evident from the drawing, said fluid device being shown in a preferred design and application as a fluid suction device 1a and herein in the scope of an advantageous integration into a metering device 2 for fluid media.

The fluid device 1 has a device housing 3 and further comprises a bending-elastic membrane element 4 which is combined with the device housing 3 such that together a chamber 5 is delimited, said chamber on operation of the fluid device 1 receiving a fluid 6 and therefore being denoted as a fluid chamber 5 for an improved differentiation.

The membrane element 4 is a constituent of a piezoelectric actuator of the fluid device 1 which is denoted as a piezoactuator 7. The piezoactuator 7 is movably suspended on the device housing with respect to this, via the membrane element 4

Expediently, the fluid device 1 comprises an electronic control device 8 which is only indicated schematically, for the actuation of the piezoactuator 7.

Although it is not necessary, it is however very advantageous if the device housing 4 3 and the piezoactuator 7 are grouped into a device unit 12 of the fluid device 1 which relates to the illustrated embodiment example.

The device housing 3 has a height axis 13, wherein the fluid device 1 however can be operated in an arbitrary alignment of the height axis 13.

The device housing 3 expediently encompasses a housing interior 14. The membrane element 4 which extends planarly in a main extension plane 15 which is preferably aligned transversely and in particular at right angles to the height axis 13 is located in the housing interior 14.

The membrane element 4 has a surface-central region 16 and a peripheral edge region 17 which extends all around this surface-central region 16. An outer contour 18 of the membrane element 4 which is preferably circular is defined by the shape of the peripheral edge region 17. As a whole, the membrane element 4 therefore expediently has the shape of a circular disc.

At its peripheral edge region 17, the membrane element 4 is fixed to the device housing 3. By way of example, the peripheral edge region 17 of the membrane element 4 is bonded to the device housing 3, wherein however other connection types are also possible. It is expediently a connection which extends in an uninterrupted manner all around the surface-central region 16 and which is preferably designed in a fluid-tight manner. Since the membrane element 4 for its part is likewise fluid-tight, the fluid chamber 5 is sealed off in a fluid-tight manner to the surroundings.

The device housing 3 preferably has a base wall 22 which extends in a plane which is at right angles to the height axis 13, and an annular side wall 23 which starting from the base wall 22 projects away from its outer edge region in the axis direction of the height axis 13 which is denoted as a height direction. The annular side wall 23 is stepped on the radial inner periphery, so that an annular shoulder 24 which is coaxial to the central height axis 13 results, on which annular shoulder the membrane element 4 lies with its peripheral edge region 17. The fluid chamber 5 is collectively delimited by the base wall 22, the annular side wall 23 and the membrane element 4.

The fluid chamber 5 is a one of two part-spaces, into which the housing interior 14 is subdivided by the membrane element 4. A second part-space which is hereinafter denoted as a control chamber 25 for a better differentiation is located on the side of the membrane element 4 which is opposite to the fluid chamber 5 in the height direction 13. The control chamber 25 is delimited laterally by a wall section of the annular side wall 23 which projects beyond the annular shoulder 24 and on the upper side which lies opposite the membrane element 4 in the height direction 13 by a cover wall 26 of the device housing, concerning which it is preferably a housing cover.

The membrane element 4 is deformable or deflectable in a bending-elastic manner at right angles to the main extension plane 15. Expressed more precisely, a membrane section which is framed by the peripheral edge region 17 and which for an improved differentiation is denoted as the membrane workings section 27 can be reversibly bent or deflected in a direction which is at right angles to the main extension plane 15 thus in the height direction 13.

The membrane element 4 preferably has spring-elastic characteristics. In particular, it is thin in the manner of a foil. By way of example, it consists of a metal and preferably of a stainless steel.

The membrane working section 27 is shown in an operational position in FIG. 2, with regard to which it is a non-deflected home position. Here, the membrane element 4 completely extends in the main extension plane 15. The membrane element 4 is preferably subjected to no mechanical biasing in the non-deflected home position of the membrane working section 27.

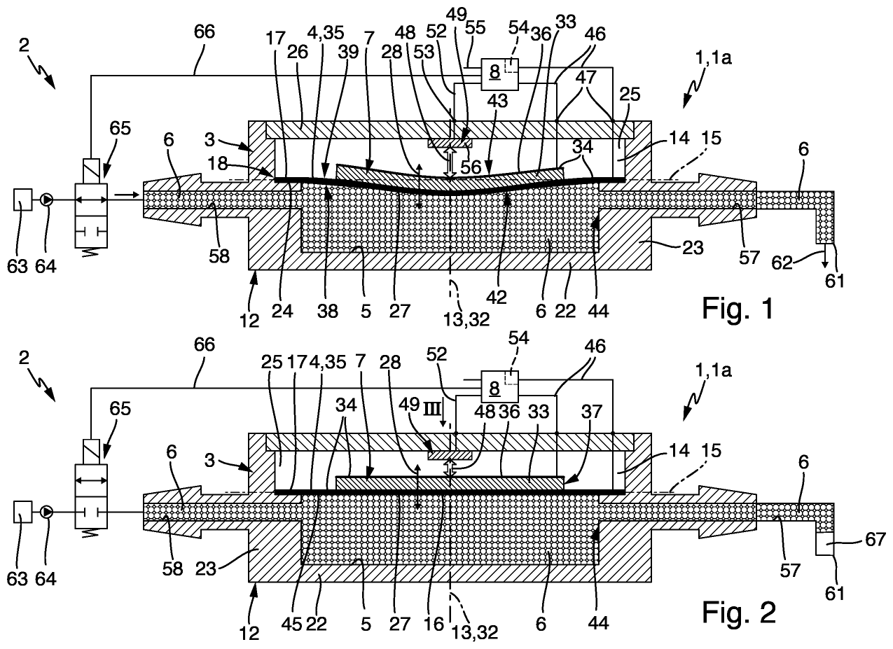

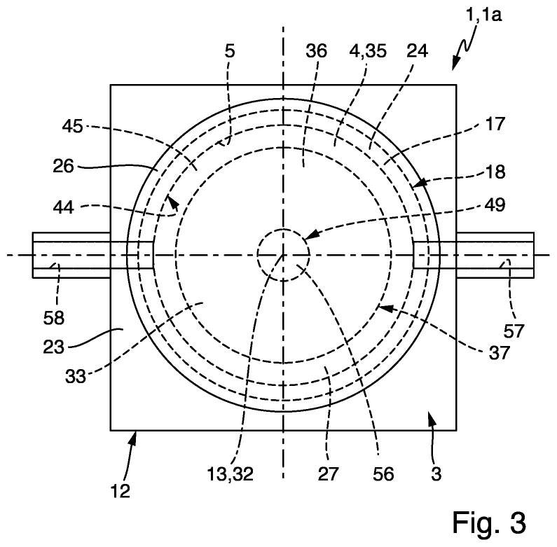

An operational position of the membrane working section 27 which is deflected in the height direction 13 with respect to the home position is evident from FIG. 1. The membrane working section 27 is hereby distanced at least regionally to the imaginary main extension plane 15 which passes through the peripheral edge region 17, wherein the height distance is greatest in the surface-central region 23 and starting from there gradually decreases concentrically towards the peripheral end section 17.

In particular, the membrane working section 27 is spherically curved in the defected operating position.

The membrane working section 27 can assume different deflected operational positions which differ from one another in their height distance which is present with respect to the main extension plane 15.

The deflection movement or bending movement between the home position and the different deflected operational positions of the membrane working section 27 is denoted as a stroke movement 28 and is illustrated in the drawing by a double arrow. The stroke movement 28 follows a working direction 32 which is rendered recognisable by a dot-dashed line and which by way of example coincides with the height direction 13 of the device housing 3. Positions of the membrane working section 27 which can be achieved in the course of the stroke movement 28 are herein denoted as stroke positions of the membrane working section 27.

The volume of the fluid chamber 5 depends on the momentary stroke position of the membrane working section 27. The further the membrane working section 27 is deflected in the direction of the base wall 22, the smaller is the fluid chamber volume.

The operating states of the fluid device 1 which are shown in FIGS. 1 and 2, in FIG. 2 define a maximum volume and in FIG. 1 a minimum volume of the fluid chamber 5.

The stroke movement 28 of the membrane working section 27 can be created by way of the piezoactuator 7. Different stroke positions of the membrane working section 27 can be set, either in a stepwise manner or preferably stepless manner, by way of the piezoactuator 7. Each set stroke position can be retained for as long as desired.

The piezoactuator 7 has at least one piezoelement 33 which has piezoelectric characteristics and which in particular consists of a piezoceramic, and furthermore an electrode arrangement 34 which flanks the at least one piezoelement 33 and consists of several electrically conductive electrodes 35, 36. A particularity of the piezoactuator 7 lies in the fact that one of the electrodes 35 is formed directly by the membrane element 4 which has corresponding electrode characteristics.

By way of the membrane element 4 by way of example consisting of a metal, without further ado it has the large-surfaced electrical conductivity which is necessary for the function as an electrode.

For an improved differentiation, hereinafter the electrode 35 which simultaneously functions as a membrane element 4 is also denoted as a membrane electrode 35.

The membrane electrode 35 is piezoelectrically inactive. It functions as a carrier substrate for the piezoelement 33. Preferably and according to the embodiment example, the piezoactuator 7 has only a single piezoelement 33. This piezoelement 33 lies between the membrane electrode 35 and a further electrode 36. Accordingly, the electrode arrangement 34 in the case of the preferred illustrated embodiment example consists of only two electrodes 35, 36, specifically the membrane electrode 35 and the further electrode 36.

The piezoelement 33 has a planar extension and is designed in a plate-like or disc-like manner A disc shape with a circular outer contour 37 is preferred for the piezoelement 33 in accordance with the illustrated embodiment example.

The disc-shaped piezoelement 33 is attached to the membrane working section 27 of the membrane element 4 forming the membrane electrode 35 at the middle of the surface of the membrane working section 27 and in particular in a coaxial manner

The membrane element 4 has a first membrane surface 38 which faces the fluid chamber 5 and a second membrane surface 39 which is opposite and away with respect to this and with regard to the illustrated embodiment example faces the control chamber 25. The piezoelement 33 is preferably attached to the second membrane surface 39. By way of this, a separation of media is present and the piezoelement 33 does not come into contact with the fluid 6 which is located in the fluid chamber 5.

The fluid 6 can be of a gaseous or liquid consistency. With regard to a preferred application of the fluid device 1, the fluid 6 is a liquid.

The piezoelement 33 is expediently bonded to the membrane element 4. Herein, the bonding surface expediently extends beyond the entire lower base surface 42 of the piezoelement 33 which faces the membrane element 4. Expediently, a fixed connection over the whole surface between the piezoelement 33 and the membrane element 4 is present.

The further electrode 36 expediently consists of an electrically conductive coating which is attached onto the upper base surface 43 of the piezoelement 33 which is opposite to the membrane element 4, wherein it is preferably applied as a metallisation.

The further electrode 36 comparable to the membrane electrode 35 could alternatively be designed as an individual, self-supporting part which is fixed to the piezoelement 33 for example by way of bonding.

The piezoactuator 7 according to the illustrated embodiment example is preferably designed as a disc translator. Thus the disc-shaped piezoelement 33 which has a circular outer contour 37 undergoes a spherical deformation with a changing curvature given the electrical actuation of the piezoactuator 7. The membrane working section 27 participates in this deformation whilst executing the stroke movement 27. Entailed by this is a uniform volume change in the fluid chamber 5 which at the peripheral side is preferably likewise contoured in a circular manner by way of a suitable shaping of the annular side wall 23.

The outer diameter of the piezoelement 33 which is measured in the main extension plane 15 is preferably less than the outer diameter of the membrane element 4.

The outer diameter of the piezoelement 33 which is measured in the main extension plane 15 is expediently less than the diameter of the fluid chamber 5 in the direct connection onto the membrane element 4, so that an annular-disc shaped membrane section 45 of the membrane element 4 is present between the radial outer periphery 37 of the piezoelement 33 and the radial inner periphery 44 of the fluid chamber 5. The peripheral edge region 17 which is used for the fixation connects onto this membrane section radially at the outside.

By way of example, the peripheral edge region 17 is immovably fastened to the device housing 3. This can be effected by way of the described bonding connection or for example also by way of a clamping connection. An alternative fixation fixedly holds the peripheral edge region 17 in a manner such that it can execute at least slight relative movements with respect to the device housing 3.

The electrode arrangement 34 is connected onto the electronic control device 8 via electrical leads 46 which are only indicated schematically. By way of example, each of the two electrodes 35, 36 are connected onto the electronic control device 8 via its own electrical lead 46. An electrical connection device 47 which is arranged on the device housing 3 is preferably assigned to the electrical leads 46 and permits a reliable connection of the electronic control device 8.

The electronic control device 8 is designed in order to provide an electrical operating voltage of a variable magnitude which can be applied to the electrode arrangement 34 via the electrical leads 46. The control device 8 has its own device, in order to permit the charge feed and the charge discharge with respect to the electrodes 35, 36, such being necessary for the variable control.

FIG. 2 illustrates an operating state concerning which the operating voltage is equal to zero, so that the piezoactuator 7 assumes the non-deflected home position. Compared to this, FIG. 1 shows an operating state with an operating voltage of greater than zero, at which the piezoactuator 7 is spherically deformed amid the reduction of the volume of the fluid chamber 5. The shape change of the piezoactuator 7 between the different operating states therefore directly creates the stroke movement 28 of the membrane working section 27.

Given the stroke movement 28, a distance between the device housing 3 and the piezoactuator 7 which is movably suspended thereon via the membrane element 4 changes, said distance being measurable in the height direction 13 and being denoted as the working distance 48. The fluid device 1 is preferably provided with a distance measuring device 49 which is envisaged to measure the aforementioned working distance 48. In this manner, on operation of the fluid device 1, the working distance 48 which changes given the stroke movement 28 of the membrane working section 27 is known. Since the working distance 48 is directly related to the volume of the fluid chamber 5, the measured working distance 48 permits precise information on the momentary volume of the fluid chamber 5. Furthermore, a volume of the fluid chamber 5 which is desired for an application case can be set by a targeted distance setting.

The distance measurement values which are determined by the distance measuring device 49, with regard to the illustrated embodiment example are fed to the electronic control device 8 which is capable of carrying out a closed-loop controlled setting of the stroke position of the membrane drive section 27 and thus indirectly also of the volume of the fluid chamber 5, on the basis of distance measurement values as actual values. The distance measuring device 49 is connected onto the electronic control device 8 via an electrical lead arrangement 52. It is preferably a releasable connection which is rendered possible by an electrical connection device 53 which is only indicated schematically and which is expediently arranged on the device housing 3.

The distance measuring device 49 is expediently integrated into the optional device unit 12.

The electronic control device 8 comprises an internal closed-loop control unit 54 for carrying out the closed-loop control measures.

The electronic control device 8 is further provided with input means 55, via which at least one setpoint of the working distance 48 which is to be set or of the volume of the fluid chamber 5 which is to be set, can be inputted, said setpoint being compared to the determined actual values of the working distance 48 in the closed-loop control unit 54, in order to output an operating voltage to the electrode arrangement 34 via the electrical leads 46 depending on the result of the comparison, by way of which operating voltage the piezoactuator 7 is deformed such that the working distance 48 and thus the volume of the fluid chamber 5 is set to the desired setpoint.

Concerning the exemplary fluid device 1 there is therefore the advantageous possibility of deforming the membrane working section 27 in a closed-loop controlled manner with regard to the distance and of accordingly indirectly also carrying out a closed loop control of the volume which is defined by the fluid chamber 5.

With regard to the distance measurement by way of the distance measuring device 49, by way of example a capacitive measuring principle is applied. Herein, what is measured is the capacitance between the further electrode 36 of the piezoactuator 7 and a measuring electrode 56 which is arranged on the device housing 3 in a manner lying opposite this further electrode 36 in the height direction 13, said capacitance arising in a distance-dependent manner The measuring electrode 56 is preferably placed lying opposite the surface-central region 16 of the membrane element 4, thus in a region in which given the stroke movement of the membrane working section 27, the distance changes are largest with respect to the device housing 3 and the piezoactuator 7.

Other measuring principles can also be used for distance measurement, for example, inductively with a planar coil, optically with a reflection light barrier, optically with a triangulator or magnetically with a Hall sensor.

In the exemplary design as a fluid suction device la, a first fluid channel 57 and a second fluid channel 58 are connected to the fluid chamber 5, of which by way of example the first fluid channel 57 forms an exit channel and the second fluid channel 58 an entry channel.

The first fluid channel 57 leads to a delivery opening 61 at which a desired fluid quantity can be delivered according to arrow 62. On using the fluid suction device la, the fluid chamber 5 and the first fluid channel 57 are normally completely filled with the fluid.

The second fluid channel 58 leads to a fluid source 63, concerning which it is for example a fluid reservoir, for example a liquid container.

A delivery pump 64 is preferably connected into the course of the second fluid channel 58 and is capable of feeding fluid which is provided by the fluid source 63, through the second fluid channel 58 into the fluid chamber 5.

Preferably, a shut-off unit 65 is arranged in the course of the second fluid channel 82 in the channel section between the fluid chamber 5 and the delivery pump 65, concerning which shut off unit by way of example it is a shut-off valve which in particular has a 2/2-way valve function. The shut-off unit 65 is expediently connected onto the electronic control device 8 via an electrical control lead 66 and can be actuated by way of this according to requirements. By way of example, the shut-off unit 86 can be selectively switched into an open position which is evident from FIG. 1 or into a shut-off position which is evident from FIG. 2. A fluid passage through the second fluid channel 58 is possible in the open position, whereas the second fluid channel 82 is blocked in the shut-off position, in order to prevent a flow of fluid into the fluid chamber 5.

Concerning a preferred operating manner of the fluid suction device la, the shut-off unit 65 in a first operating phase which is evident from FIG. 1 is switched into the open position, wherein the delivery pump 85 which is in operation delivers a fluid 6 out of the fluid source 63 through the second fluid channel 58, the fluid chamber 5 and the first fluid channel 57 to the delivery opening 61. The fluid exits at the delivery opening 61 according to arrow 62 for the designated use.

The fluid transport and the fluid delivery take place until the shut-off unit 86 is switched over into the shut-off position by the control device 8, so that the fluid suction device 1a gets into the second operating phase according to FIG. 2. Here, the fluid flow and the fluid delivery at the delivery opening 83 are then stopped.

Evidently, a metered fluid delivery at the delivery opening 61 can be effected during the time intervals which are selected between the open position and the shut-off position of the shut-off unit 65. Inasmuch as this is concerned, the fluid suction device 1a can be advantageously used as a metering device 2 or in a metering device 2 according to the illustrated embodiment example.

The changeability of the volume of the fluid chamber 5 in the case of the outlined metering application can be used in the second operating phase according to FIG. 2, to prevent an undesired post-dripping of fluid at the delivery opening 61. For this, the volume of the fluid chamber 5 can be enlarged after the switching-over of the shut-off unit 65 into the shut-off position by way of a corresponding actuation of the piezoactuator 7, so that a underpressure arises in the fluid chamber 5, such resulting in fluid 6 which is situated in the first fluid channel 57 being sucked back into the fluid chamber 5. By way of this, the fluid column which is located in the first fluid channel 57 is drawn back and an intermediate space 67 which is filled with air and which prevents a fluid exit forms between this fluid column and the delivery opening 61.

The exemplary fluid suction device 1a in particular can be used to the extent that the piezoactuator 7 during a first operating phase according to FIG. 5 is activated by way of applying an operating voltage such that the membrane working section 27 is deflected in the direction of the fluid chamber 5 and the fluid chamber 5 is set to a reduced chamber volume. In order to generate the desired underpressure, in the second operating phase according to FIG. 2 the operating voltage for the piezoactuator 7 is reduced, so that the membrane working section 27 is moved somewhat in the direction of the non-deflected home position according to FIG. 2 or completely returns into this non-deflected home position, which entails an increase of the volume of the fluid chamber 5 which causes a underpressure and entails the previously outlined fluid back-sucking effect.

The desired volume of the fluid chamber 5 or the desired volume change can be set and specified in a very precise manner with the help of the electronic control device 8. In this manner, one can specify in a very exact manner the quantity of fluid which is to be sucked back.

The fluid suction device 1a by way of example can be used in the context of a metering device or dosing device 2 which is used to apply the necessary photo resist on semiconductor manufacture. Another possible application is for example is a metered delivery of liquid into the cavities of micro titration plates in laboratory application.

What is claimed is:

1. A fluid device comprising a fluid chamber which is designed for receiving a fluid and which is commonly delimited by a device housing and a bending-elastic membrane element which has a planar extension in a main extension plane, wherein the membrane element at its peripheral edge region is fixed to the device housing and wherein a membrane working section of the membrane element which is framed by the peripheral edge region, for the change of the volume of the fluid chamber is elastically deflectable in a working direction which is orientated transversely to the main extension plane by a piezoactuator of the fluid device whilst carrying out a stroke movement, wherein the piezoactuator comprises an electrode arrangement, to which an operating voltage which creates the stroke movement of the membrane working section can be applied in a variable magnitude, and wherein the membrane element is a functional constituent of the piezoactuator by way of said membrane element directly forming an electrically conductive electrode of the electrode arrangement.

2. The fluid device according to claim 1, wherein the membrane element consists of an electrically conductive metal.

3. The fluid device according to claim 1, wherein the membrane element has two membrane surfaces which are facing away from one another in the working direction, wherein the piezoactuator comprises a piezoelement which is fixed to one of the two membrane surfaces, has piezoelectric characteristics and on whose side which is facing away from the membrane element in the working direction a further electrode of the electrode arrangement is arranged, said further electrode having a planar extension.

4. The fluid device according to claim 3, wherein the piezoelement is bonded to the membrane element.

5. The fluid device according to claim 3, wherein the further electrode consists of an electrically conductive coating of the piezoelement.

6. The fluid device according to claim 3, wherein the piezoelement is attached to the membrane surface of the membrane element which is facing away from the fluid chamber.

7. The fluid device according to claim 3, wherein the piezoelement has a circular outer contour.

8. The fluid device according to claim 1, wherein the membrane element has a circular contour on its peripheral edge region.

9. The fluid device according to claim 1, wherein the piezoactuator is a disc translator.

10. The fluid device according to claim 1, wherein the membrane element at its peripheral edge region is connected to the device housing in a fluid tight manner all around.

11. The fluid device according to claim 1, wherein the fluid device has an electronic control device which is electrically connectable or connected onto the electrode arrangement and by which by way of specifying an operating voltage of a suitable magnitude at least one stroke position of the membrane working element which is assumed with respect to the device housing can be set.

12. The fluid device according to claim 1, wherein the fluid device is provided with a distance measuring device which is designed for measuring a working distance between the piezoactuator and the device housing, said working distance changing given the stroke movement of the membrane working section.

13. The fluid device according to claim 12, wherein the fluid device has an electronic control device which is electrically connectable or connected onto the electrode arrangement and by which by way of specifying an operating voltage of a suitable magnitude at least one stroke position of the membrane working element which is assumed with respect to the device housing can be set, wherein the electronic control device is designed for a closed-loop controlled setting of the stroke position of the membrane working section, said setting being based on the distance measurement values provided by the distance measuring device.

14. The fluid device according to claim 1, wherein the fluid device is a fluid suction device, concerning which an underpressure can be created by way of a volume increase of the fluid chamber which is caused by way of the piezoactuator, by way of which underpressure a fluid which is located in a first fluid channel which is connected to the fluid chamber can be sucked into the fluid chamber.

15. The fluid device according to claim 14, wherein additionally a second fluid channel is connected to the fluid chamber, wherein the fluid can flow into the fluid chamber through the second fluid channel and the fluid can flow out of the fluid chamber through the first fluid channel, wherein a shut-off unit is assigned to the second fluid channel, by way of which shut-off unit the second fluid channel can be shut off in order to prevent a flow of fluid into the fluid chamber through the second fluid channel, and wherein fluid which has flowed out of the fluid chamber into the first fluid channel, given the second fluid channel being shut-off by the shut-off unit can be sucked back into the fluid chamber by way of creating the underpres sure in the fluid chamber.

16. The fluid device according to claim 2, wherein the membrane element is made of stainless steel.

17. The fluid device according to claim 7, wherein the piezoelement is arranged on the membrane element at the middle of the surface of the membrane element.
